(19) United States
(12) Patent Application Publication
(10) Pub. No.: US 2014/0218626 A1
(43) Pub. Date: Aug. 7, 2014

(54) SELF-LUMINOUS DISPLAY PANEL, AND DISPLAY APPARATUS HAVING THE SAME

(71) Applicant: SAMSUNG ELECTRONICS CO., LTD., Suwon-si (KR)

(72) Inventors: Il-yong JUNG, Yongin-si (KR); Seong-eun CHUNG, Seoul (KR)

(73) Assignee: SAMSUNG ELECTRONICS CO., LTD., Suwon-si (KR)

(21) Appl. No.: 14/163,731

(22) Filed: Jan. 24, 2014

(30) Foreign Application Priority Data
Feb. 7, 2013 (KR) 10-2013-0013986

(51) Int. Cl. H01L 51/52; H04N 5/70; H01L 27/32

(52) U.S. Cl. CPC H01L 51/5293; H01L 27/3211; H04N 5/70
USPC 348/803; 257/40

(57) ABSTRACT

A display apparatus includes: a signal receiver configured to receive an image signal; a signal processor configured to process the image signal received by the signal receiver; and a display panel configured to display the image signal processed by the signal processor as a processed image, wherein the display panel includes: a glass substrate; a first electrode layer; a second electrode layer disposed between the first electrode layer and the glass substrate; a light emitting layer disposed between the first electrode layer and the second electrode layer, configured to generate a plurality of colors of light, and configured to emit the light to the glass substrate; a linear pattern layer formed on a surface of the glass substrate and including linear bars extending in one direction to transmit a preset polarizing direction of light; and a phase retardation layer disposed between the second electrode layer and the linear pattern layer.

### CROSS-REFERENCE TO RELATED APPLICATION

This application claims priority from Korean Patent Application No. 10-2013-0013986, filed on Feb. 7, 2013 in the Korean Intellectual Property Office, the disclosure of which is incorporated herein by reference, in its entirety.

### BACKGROUND

1. Field

Apparatuses consistent with the exemplary embodiments relate to a display panel which displays an image on a surface thereof and a display apparatus having the same. More particularly, the exemplary embodiments relate to a self-luminous display panel which displays an image by autonomously generating light without a separate backlight, and has a structure for preventing external light entering the panel from the outside from being reflected in the panel and exited to the outside, and a display apparatus having the same.

2. Description of the Related Art

A display apparatus is a device which includes a display panel which displays images to present broadcast signals or various formats of image signals or image data, and is configured as a TV, a monitor, or the like. The display panel is configured as various types of display panels based on characteristics thereof, such as a liquid crystal display (LCD) panel, a plasma display panel (PDP), or the like, and is employed for a variety of display apparatuses.

Display panels used for a display apparatus may be classified into a light receiving panel and a self-luminous panel, depending on a method of light generation. The light receiving panel does not emit light by itself and thus includes a separate backlight to generate and provide light to the panel, and an example thereof includes an LCD panel. The self-luminous panel emits light by itself and thus does not need a backlight, and an example thereof includes an organic light emitting diode (OLED) panel.

The self-luminous display panel includes a light emitting layer on the inside to generate light. The light emitting layer is divided into a type that emits white light overall and a type in which sub-pixels respectively emit red, green and blue (RGB) colors of light. Unlike the former type of display panel, the latter type does not need a color filter layer since the light emitting layer emits RGB colors of light by sub-pixels, whereas incident external light may be reflected in the panel to cause a decrease in contrast.

### SUMMARY

A display apparatus may include: a signal receiver configured to receive an image signal; a signal processor configured to process the image signal received by the signal receiver according to a preset image processing process; and a display panel configured to display the image signal processed by the signal processor as an image, wherein the display panel includes: a glass substrate; a first electrode layer; a second electrode layer disposed between the first electrode layer and the glass substrate; a light emitting layer disposed between the first electrode layer and the second electrode layer, configured to generate a plurality of colors of light based on holes and electrons transported by a voltage applied to the first electrode layer and the second electrode layer, and configured to emit the light to the glass substrate; a linear pattern layer formed on the glass substrate, the linear pattern layer includes linear bars extending in one direction to transmit a preset polarizing direction of light; and a phase retardation layer disposed between the second electrode layer and the linear pattern layer, and configured to emit entering light by retarding a phase of the light.

The linear bars may each include a metal layer configured to reflect light to inside of the display panel, in a polarized direction that the linear pattern layer does not transmit.

The linear bar may further include an insulating layer formed on a portion of the metal layer and toward the phase retardation layer.

The linear bar may further include a light absorbing layer disposed between the metal layer and the glass substrate and including a light absorbing material.

The phase retardation layer may retard a phase of light by λ/4.

An extending direction of the linear bar may be determined based on the preset polarizing direction so that the linear pattern layer transmits the preset polarizing direction of light.

The light emitting layer may generate red, green and blue colors of light by sub-pixels.

A self-luminous display panel may include: a glass substrate; a first electrode layer; a second electrode layer disposed between the first electrode layer and the glass substrate; a light emitting layer disposed between the first electrode layer and the second electrode layer, the light emitting layer being configured to generate a plurality of colors of light based on holes and electrons transported by voltage applied to the first electrode layer and the second electrode layer, and configured to emit the light to the glass substrate; a linear pattern layer formed on the glass substrate and including linear bars extending in one direction to transmit a preset polarizing direction of light; and a phase retardation layer disposed between the second electrode layer and the linear pattern layer, and configured to emit entering light by retarding a phase of the light.

The linear bar may include a metal layer to reflect light in a polarized direction that the linear pattern layer does not transmit to the inside of the display panel.

The linear bar may further include an insulating layer formed on a portion of the metal layer and extending toward the phase retardation layer.

The linear bar may further include a light absorbing layer disposed between the metal layer and the glass substrate and including a light absorbing material.

The phase retardation layer may retard a phase of light by λ/4.

The extending direction of the linear pattern layer may be determined based on the preset polarizing direction so that the linear pattern layer transmits the preset polarizing direction of light.

The light emitting layer may generate red, green and blue colors of light by sub-pixels.

An aspect of an exemplary embodiment may further provide a self-luminous display panel including: a glass substrate; a first electrode layer; a second electrode layer disposed between the first electrode layer and the glass substrate; a linear pattern layer formed on a surface of the glass substrate and comprising linear bars extending in one direction to transmit light in a preset polarizing direction; and a phase retardation layer disposed between the second electrode layer and the linear pattern layer, and configured to emit entering light by retarding a phase of the light, wherein the phase retarded light entering the self-luminous display panel, is then reflected by the first and second electrodes back towards the linear pattern layer through the phase retardation layer and is reflected back towards the phase retardation layer, whereby the entering light does not exit to the outside.

### BRIEF DESCRIPTION OF THE DRAWINGS

The above and/or other aspects will become apparent and more readily appreciated from the following description of the exemplary embodiments, taken in conjunction with the accompanying drawings, in which:

FIG. 1 is a block diagram which illustrates a configuration of a display apparatus, according to a first exemplary embodiment.

FIG. 2 is a lateral cross-sectional view which schematically illustrates a layered structure of a display panel of FIG. 1.

FIG. 3 illustrates changes in polarizing characteristics, by stages, after external light enters the display panel of FIG. 2.

FIG. 4 is a lateral cross-sectional view which schematically illustrates a layered structure of a display panel, according to a second exemplary embodiment.

FIG. 5 is a perspective view which illustrates a main part of a linear pattern layer in the display panel of FIG. 4.

FIGS. 6, 7 and 8 are lateral cross-sectional views which illustrate linear bars in the display panel of FIG. 4.

FIG. 9 illustrates changes in polarizing characteristics, by stages, after external light enters the display panel of FIG. 4.

### DETAILED DESCRIPTION OF EXEMPLARY EMBODIMENTS

Below, exemplary embodiments will be described in detail with reference to the accompanying drawings. The exemplary embodiments may be embodied in various forms without being limited to the exemplary embodiments set forth herein. Descriptions of well-known parts are omitted for clarity and conciseness, and like reference numerals refer to like elements throughout.

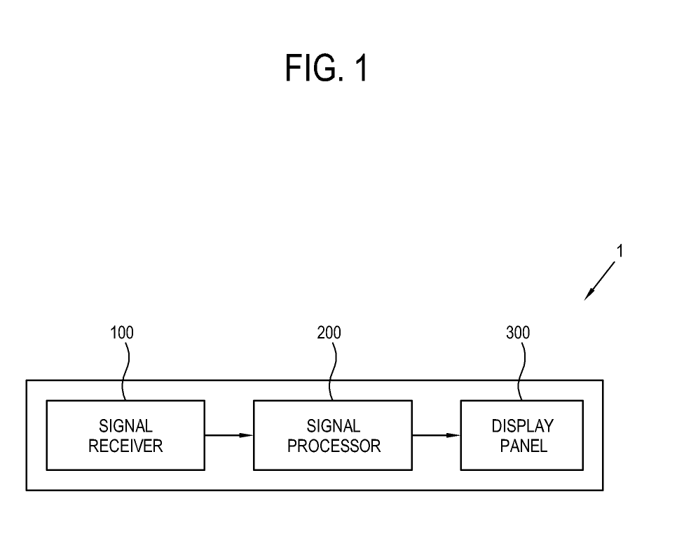

FIG. 1 is a block diagram which illustrates a configuration of a display apparatus, 1 according to a first exemplary embodiment.

As shown in FIG. 1, the display apparatus 1 includes a signal receiver 100 to receive an image signal, a signal processor 200 to process an image signal received by the signal receiver 100 according to a preset image processing process, and a display panel 300 to display an image based on an image signal processed by signal processor 200.

Although the exemplary embodiment will be illustrated with a TV as the display apparatus 1, the display apparatus 1 is not limited to a TV. For example, the idea of the exemplary embodiments may be applied to various kinds of display apparatuses 1 which are capable of displaying an image based on an image signal/image data provided from the outside or stored therein, such as a portable multimedia player and a mobile phone.

The signal receiver 100 receives an image signal or image data and transmits the image signal or image data to the signal processor 200. The signal receiver 100 may be configured according to various types of standards of received image signals and configurations of the display apparatus 1. For example, the signal receiver 100 may receive a radio frequency (RF) signal wirelessly transmitted from a broadcast station (not shown) or various image signals in accordance with composite video, component video, super video, SCART, high definition multimedia interface (HDMI), DisplayPort, unified display interface (UDI) or wireless HD standards via a cable. When the image signal is a broadcast signal, the signal receiver 100 includes a tuner to tune the broadcast signal by each channel. Alternatively, the signal receiver 100 may receive an image data packet from a server (not shown), through a network.

The signal processor 200 performs various image processing processes on the image signal received by the signal receiver 100. The signal processor 200 outputs a processed image signal to the display panel 300, thereby displaying on display panel 300 an image based on the processed image signal.

The signal processor 200 may perform any kind of image processing, without being limited to, for example, decoding which corresponds to an image format of image data, de-interlacing to convert interlaced image data into a progressive form, scaling to adjust image data to a preset resolution, noise reduction to improve image quality, detail enhancement, frame refresh rate conversion, or the like.

The signal processor 200 may be provided as an image processing board (not shown) formed by mounting an integrated multi-functional component, such as a system on chip (SOC), or separate components to independently conduct individual processes on a printed circuit board, and be embedded in the display apparatus 1.

The display panel 300 displays an image based on an image signal output from the signal processor 200. The display panel 300 according to an exemplary embodiment includes a self-luminous panel, instead of a non-light emitting panel, such as a liquid crystal display (LCD) panel. For example, the display panel 300 may be configured as an organic light emitting diode (OLED) panel.

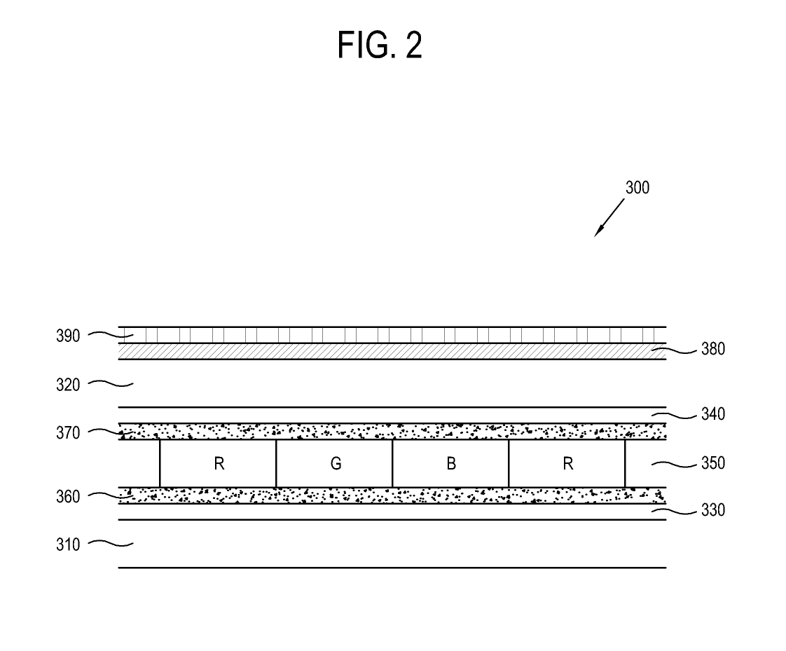

Hereinafter, a structure of the display panel 300 according to an exemplary embodiment will be described with reference to FIG. 2.

FIG. 2 is a lateral cross-sectional view which schematically illustrates a layered structure of the display panel 300.

As shown in FIG. 2, the display panel 300 includes a first glass substrate 310, a second glass substrate 320 disposed to face the first glass substrate 310, a first electrode layer 330, a second electrode layer 340 disposed to face the first electrode layer 330, a light emitting layer 350 disposed between the first electrode layer 330 and the second electrode layer 340, an electron transport layer 360 disposed between the first electrode layer 330 and the light emitting layer 350, a hole transport layer 370 disposed between the light emitting layer 350 and the second electrode layer 340, a phase retardation layer 380 stacked on the second glass substrate 320, and a polarizing layer 390 stacked on the phase retardation layer 380.

In the following description, directional expressions “upper/upwards” and “lower/downwards” are used to describe the relative arrangement or stacked relationship between constituents in a traveling direction of light exiting from the display panel 300. For instance, when light generated in the display panel 300 exits upwards from the display panel 300 in FIG. 2, the display panel 300 has a structure in which the electron transport layer 360, the light emitting layer 350, the hole transport layer 370, the second electrode layer 240, the second glass substrate 320, the phase retardation layer 380 and the polarizing layer 390 are sequentially stacked on the first electrode layer 330.

Hereinafter, a structure of generating light in the display panel 300 will be described.

The first electrode layer 330 and the second electrode layer 340 serve as a cathode layer and an anode layer, respectively. As negative (−) and positive (+) voltages are respectively applied to the first electrode layer 330 and the second electrode layer 340, electrons are generated in the first electrode layer 330 and holes are generated in the second electrode layer 340. The electron transport layer 360 transports the electrons in the first electrode layer 330 to the light emitting layer 350, and the hole transport layer 370 transports the holes in the second electrode layer 340 to the light emitting layer 350.

The electrons and holes transported to the light emitting layer 350 form excitons in the light emitting layer 350. An exciton is a neutral particle that is a bound state of an electron and a hole as a unit freely traveling in a nonmetallic crystal. An exciton emits light when changing from an excited state to a base state, and accordingly the light emitting layer 350 generates and emits light.

There are two ways a light emitting layer generates light in the OLED panel. First, the light emitting layer generates white light, in which case a color filter layer is used to change white light into red, green and blue (RGB) colors of light, is needed above the light emitting layer.

Second, the light emitting layer is divided into sub-pixels that each generate RGB colors of light, in which case a color filter layer is not necessary since each color of light is emitted from the light emitting layer. In an exemplary embodiment, the light emitting layer 350 generates RGB colors of light, and thus a color filter layer is not employed for the display panel 300.

The light emitting layer 350 may improve light emitting efficiency by enhancing generation amounts or transport amounts of holes and electrons. To this end, the display panel 300 may further include an electron injection layer (not shown) disposed between the first electrode layer 330 and the electron transport layer 360 and a hole injection layer (not shown) disposed between the hole transport layer 370 and the second electrode layer 340 based on a design thereof.

In this structure of the display panel 300, however, when external light enters an inside portion of the display panel 300 through the second glass substrate 320, the entering external light may be reflected in the display panel 300 and exit out of the display panel 300. As a result, a contrast ratio of an image displayed on the display panel 300 may be reduced, leading to deterioration in image quality.

Thus, in an exemplary embodiment, the polarizing layer 390 and the phase retardation layer 380 are employed for the display apparatus 300. The polarizing layer 390 transmits a preset polarizing direction of light only, while the phase retardation layer 380 allows entering light to exit by retarding a phase of the light by λ/4. Here, λ is a wavelength of light.

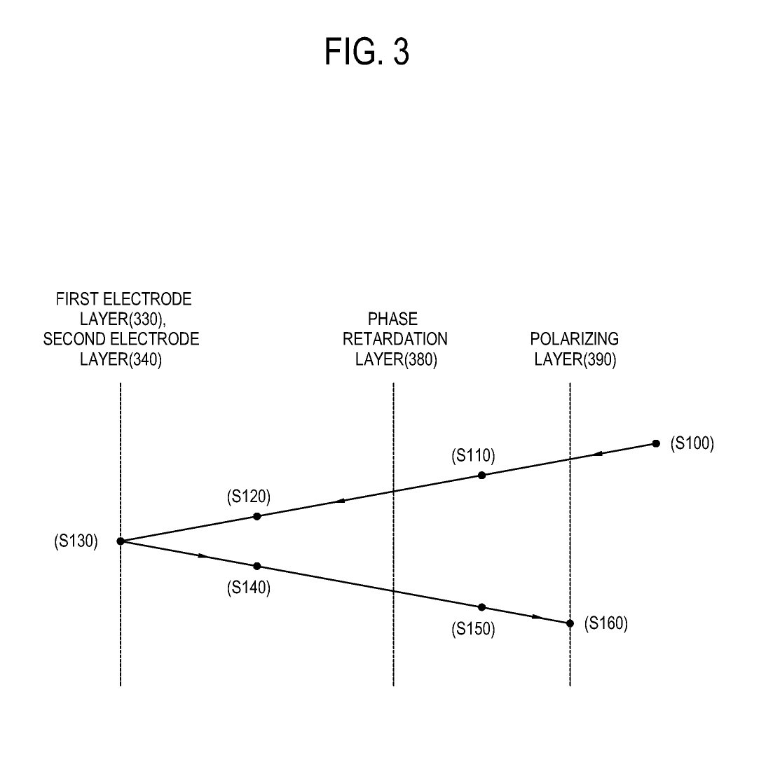

FIG. 3 illustrates changes in polarizing characteristics, by stages, after external light enters the display panel 300.

As shown in FIG. 3, the external light enters the polarizing layer 390 from outside the display panel and passes through the polarizing layer 390 and the phase retardation layer 380. The external light passing through the phase retardation layer 380 is reflected by the second electrode layer 340 or the first electrode layer 330, passes through the phase retardation layer 380 again and then reaches the polarizing layer 390.

For purposes of convenience, the stages after the external light entering the display panel 300 may be divided according to a light traveling order into an initial stage S100 before the external light reaches the display panel 300, a stage S110 after the external light has passed through the polarizing layer 390, a stage S120 after the external light has passed through the phase retardation layer 380, a stage S130 in which the external light is reflected by the first electrode layer 330 or the second electrode layer 340, a stage S140 before the reflected external light reaches the phase retardation layer 380, a stage S150 after the external light has passed through the phase retardation layer 380, and a stage S160 in which the external light reaches and enters the polarizing layer 390.

In the initial stage S100, the external light is a mixed state of circularly polarized light and linearly polarized P and S waves. Since the polarizing layer 390 transmits only a particular polarizing direction of light, for example, linearly polarized P waves of light, the linearly polarized P waves of light alone exist in the stage S110 after the external light has passed through the polarizing layer 390.

As the phase retardation layer 380 retards a phase of light by λ/4, the linearly polarized P waves of light, having passed through the phase retardation layer 380 (S120), is converted into circularly polarized light. The circularly polarized light is reflected by the first electrode layer 330 or the second electrode layer 340 (S130), and maintains polarizing characteristics thereof while heading back to the phase retardation layer 380 (S140).

When the circularly polarized light passes through the phase retardation layer 380 (S150), the circularly polarized light is converted into linearly polarized S waves of light by the phase retardation layer 380. As described above, the polarizing layer 390 transmits the linearly polarized P waves of light only. Thus, when the linearly polarized S waves of light enter the polarizing layer 390 (S160), the linearly polarized S waves of light do not pass through the polarizing layer 390 and thus does not exit out of the display panel 300.

That is, in the foregoing structure, external light entering the display panel 300 is not reflected out of the display panel 300, thereby preventing a decrease in a contrast ratio.

However, in this structure that the polarizing layer 390 transmits a particular polarizing direction of light only, the polarizing layer 390 also transmits only a particular polarizing direction of light generated from the light emitting layer 350 other than external light. That is, the polarizing layer 390 may cause a decrease in light efficiency of the display panel 300 to about 50%.

Accordingly, the following configuration is proposed.

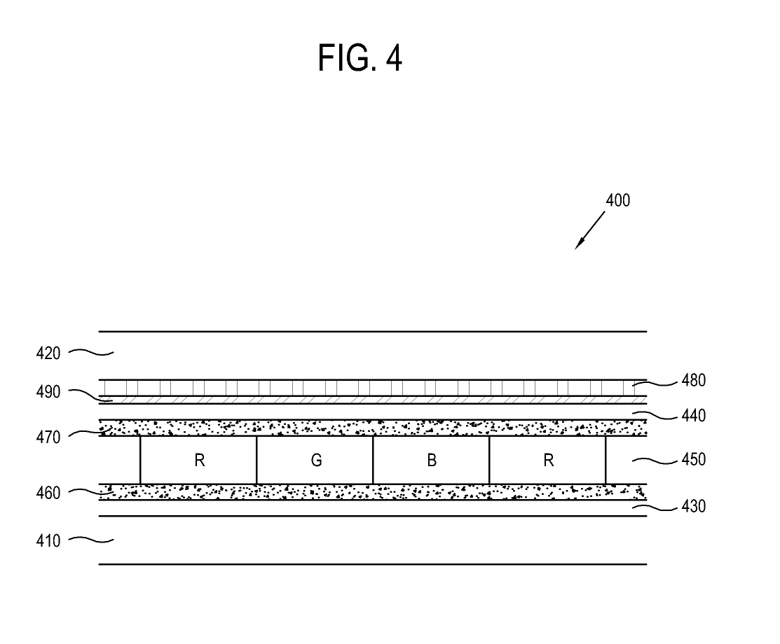

FIG. 4 is a lateral cross-sectional view schematically illustrating a layered structure of a display panel 400 according to a second exemplary embodiment.

As shown in FIG. 4, the display panel 400 includes a first glass substrate 410, a second glass substrate 420, a first electrode layer 430, a second electrode layer 440, a light emitting layer 450, an electron transport layer 460 and a hole transport layer 470. These elements serve the same functions as those of the equivalent elements in the first exemplary embodiment, and thus descriptions thereof are omitted herein.

In addition, the display panel 400 includes a linear pattern layer 480 disposed between the second glass substrate 420 and the second electrode layer 440 and a phase retardation layer 490 disposed between the linear pattern layer 480 and the second electrode layer 440.

The linear pattern layer 480 includes a plurality of parallel linear bars extending in one direction on a lower surface of the second glass substrate 420. The lower surface of the second glass substrate 420 refers to a surface facing the second electrode layer 440. The linear bars are arranged parallel with each other at a preset pitch toward the second electrode layer 440.

The phase retardation layer 490 allows entering light to exit by retarding a phase of the light by λ/4 like in the first embodiment.

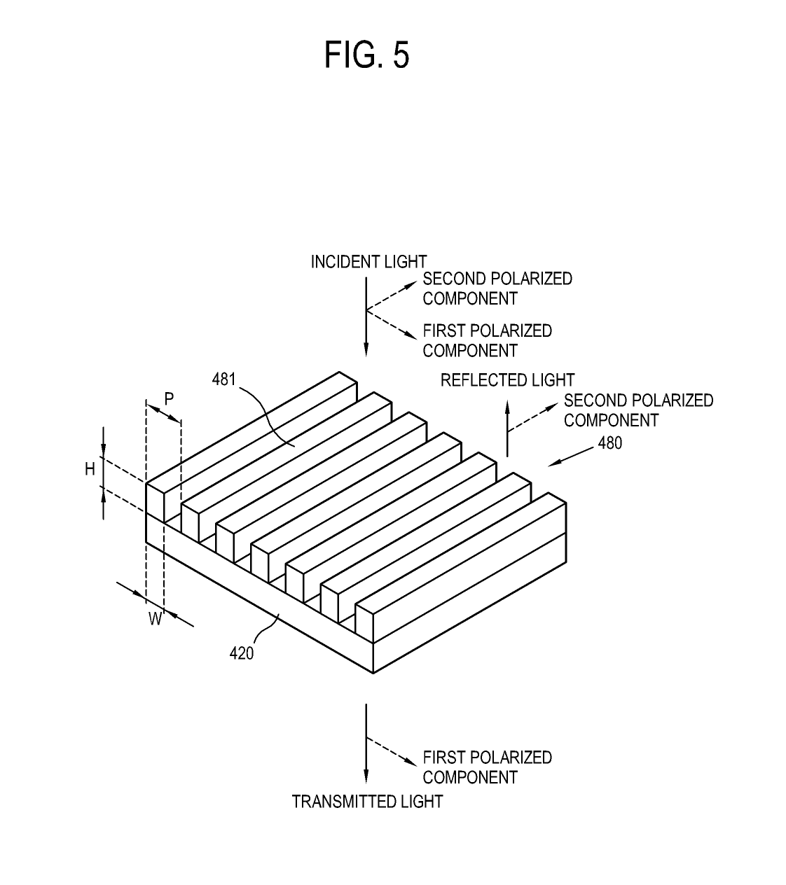

FIG. 5 is a perspective view illustrating a main portion of the linear pattern layer 480 in the display panel 400. FIG. 5 shows the lower surface of the second glass substrate 420 and the linear pattern layer 480 so as to clearly present the linear pattern layer 480.

As shown in FIG. 5, the linear pattern layer 480 is formed by arranging a plurality of linear bars extending in a particular direction, parallel with each other, on the lower substrate of the second glass substrate 420. The linear bars 481 have a preset height H, width W, and pitch P.

When the pitch P of the linear bars 481 is adjusted to ½ of a wavelength of light, only transmitted light and reflected light are formed without diffracted waves. Slits are formed between two adjacent linear bars 481, and while entering light is passing through the slits, a first polarized component in a first polarizing direction perpendicular to an extending direction of the linear bars 481 passes through the linear pattern layer 480. On the contrary, a second polarized component in a second polarizing direction which is parallel with the extending direction of the linear bars 481 is reflected again. That is, due to this structure of the linear bars 481, light passing through the linear pattern layer 480 is polarized-filtered in the first polarizing direction.

That is, the extending direction of the linear bars 481 is determined based on a polarizing direction of light that the linear pattern layer 480 transmits.

The linear bars 481 include metal materials reflecting light. Thus, light that does not pass through the linear pattern layer 480 is reflected by the linear bars 481 back inside the display panel 400 and reflected again by the first electrode layer 430 or the second electrode layer 440, thereby being transmitted back to the linear pattern layer 480 along with light exiting from the light emitting layer 450. That is, unlike the polarizing layer 390 of the first exemplary embodiment absorbing light that does not pass, the linear pattern layer 480 does not absorb but rather re-reflects light not passing, thereby achieving recycling of light.

The linear pattern layer 480 is formed by depositing a metal layer on the second glass substrate 420 and patterning the linear bars 481 by nano imprint lithography (NIL). When a polarizing direction of entering light is parallel with the linear bars 481, the light is reflected by the linear pattern layer 480. When the polarizing direction of entering light is perpendicular to the linear bars 481, the light is transmitted.

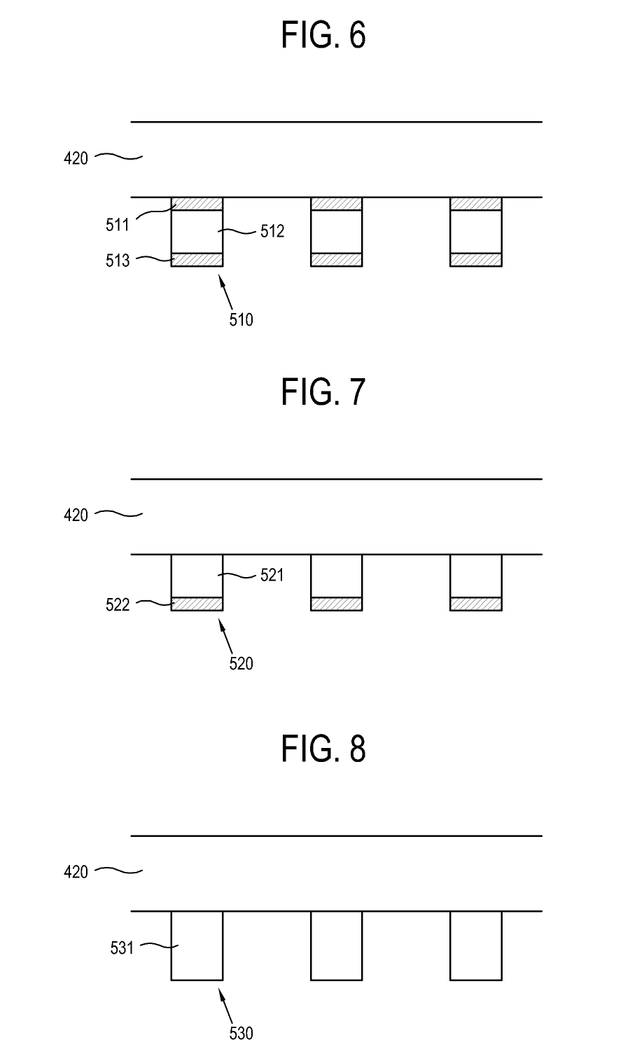

FIGS. 6, 7 and 8 are lateral cross-sectional views illustrating linear bars according to exemplary embodiments.

As shown in FIG. 6, one linear bar 510 is formed by sequentially stacking a light absorbing layer 511, a metal layer 512 and an insulating layer 513 on the lower surface of the second glass substrate 420 in a direction toward an inside of the display panel 400.

The light absorbing layer 511 absorbs part of external light incident through the second glass substrate 420. The light absorbing layer 511 includes various materials, such as AlAs, GaAs, InGaAs, GaP, GaN, InN, CdTe, Ni—P, carbon nanotube, Ag2S, Cr2O3 and black paint.

The metal layer 512 includes materials with good light reflectance, such as Au, Al, Cu, or Ag and reflects a non-transmitted polarized component of light to the inside of the display panel 400.

The insulating layer 513 protects the metal layer 512 and includes SiO2.

As shown in FIG. 7, one linear bar 520 may be formed by sequentially stacking a metal layer 521 and an insulating layer 522 on the lower surface of the second glass substrate 420. The metal layer 521 and the insulating layer 522 are substantially the same as the metal layer 512 and the insulating layer 513 shown in FIG. 6.

As shown in FIG. 8, one linear bar 530 may include a metal layer 531 only on the lower surface of the second glass substrate 420. The metal layer 531 is substantially the same as the metal layer 512 shown in FIG. 6.

As illustrated with reference to FIGS. 6 to 8, the linear bars 510, 520 and 530 respectively include the metal layers 512, 521 and 531 to reflect light, so that a non-transmitted polarized component of light may not be absorbed but be reflected.

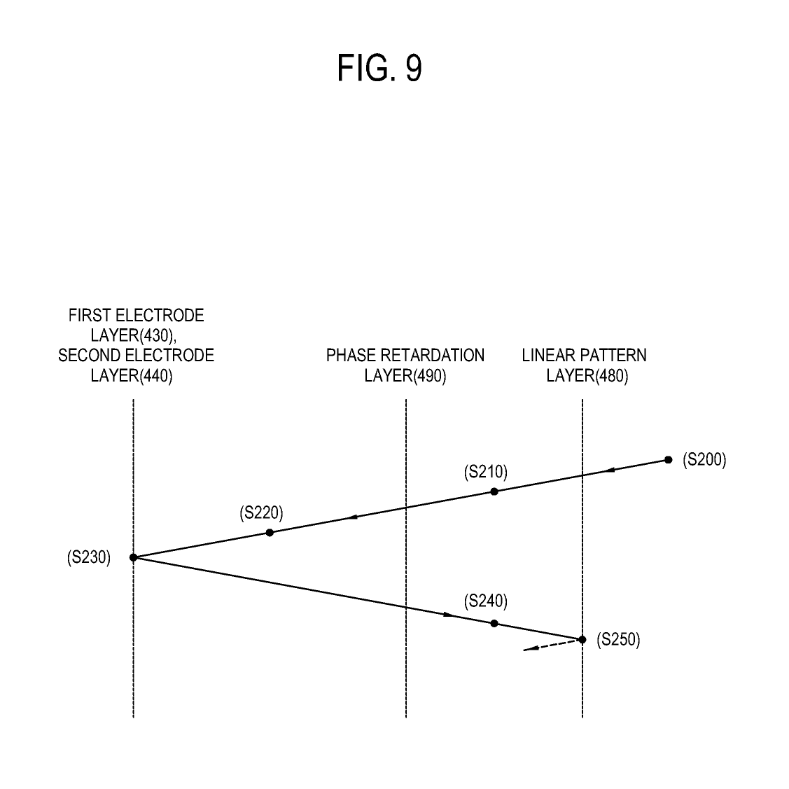

FIG. 9 illustrates changes in polarizing characteristics, by stages, after external light enters the display panel 400.

As shown in FIG. 9, the external light enters the linear pattern layer 480 from the outside and passes through the linear pattern layer 480 and the phase retardation layer 490. The external light passing through the phase retardation layer 490 is reflected by the second electrode layer 440 or the first electrode layer 430, passes through the phase retardation layer 490 again and then reaches the linear pattern layer 480.

For convenience, the stages after the external light enters the display panel 400 may be divided according to a light traveling order into an initial stage S200 before the external light does not yet reach the display panel 400, a stage S210 after the external light has passed through the linear pattern layer 480, a stage S220 after the external light has passed through the phase retardation layer 490, a stage S230 in which the external light is reflected by the first electrode layer 430 or the second electrode layer 440, a stage S240 after the reflected external light has passed through the phase retardation layer 490, and a stage S250 in which the external light reaches and enters the linear pattern layer 480.

In the initial stage S200, the external light is a mixed state of circularly polarized light and linearly polarized P and S waves. Since the linear pattern layer 480 transmits only a particular polarizing direction of light, for example, linearly polarized P waves of light, the linearly polarized P waves of light alone exist in the stage S210 after the external light has passed through the linear pattern layer 480.

As the phase retardation layer 490 retards a phase of light by λ/4, the linearly polarized P waves of light having passed through the phase retardation layer 490 (S220) is converted into circularly polarized light. The circularly polarized light is reflected by the first electrode layer 430 or the second electrode layer 440 (S230). When the circularly polarized light passes through the phase retardation layer 490 (S240), the circularly polarized light is converted into linearly polarized S waves of light by the phase retardation layer 490.

When the linearly polarized S waves of light enter the linear pattern layer 480 (S250), the linear pattern layer 480 does not transmit the linearly polarized S waves of light since the linear pattern layer 480 transmits the linearly polarized P waves of light only. Here, unlike the polarizing layer 380 that absorbs the linearly polarized S waves of light in the first embodiment, the linear pattern layer 480 reflects the linearly polarized S waves of light to the phase retardation layer 490 so that the light does not exit to the outside.

Accordingly, surface reflection by external light is reduced, a contrast ratio of an image is improved, and light transmittance of the display panel 400 is enhanced, thereby improving brightness of an image.

Although a few exemplary embodiments have been shown and described, it will be appreciated by those skilled in the art that changes may be made in these exemplary embodiments without departing from the principles and spirit of the invention, the scope of which is defined in the appended claims and their equivalents.

What is claimed is:

1. A display apparatus comprising:
a signal receiver configured to receive an image signal;
a signal processor configured to process the image signal received by the signal receiver according to a preset image processing process; and
a display panel configured to display the image signal processed by the signal processing unit as a processed image,
wherein the display panel comprises:
a glass substrate;
a first electrode layer;
a second electrode layer disposed between the first electrode layer and the glass substrate;
a light emitting layer disposed between the first electrode layer and the second electrode layer, configured to generate a plurality of colors of light based on holes and electrons transported by voltage applied to the first electrode layer and the second electrode layer, and configured to emit the light to the glass substrate;
a linear pattern layer formed on the glass substrate and comprising linear bars extending in one direction to transmit the light in a preset polarizing direction; and
a phase retardation layer disposed between the second electrode layer and the linear pattern layer, and configured to emit entering light by retarding a phase of the light.

2. The display apparatus of claim 1, wherein the linear bar comprises a metal layer configured to reflect light in a polarized direction to an inside of the display panel that the linear pattern layer does not transmit.

3. The display apparatus of claim 2, wherein the linear bar further comprises an insulating layer formed on a portion of the metal layer and extending in a direction toward the phase retardation layer.

4. The display apparatus of claim 2, wherein the linear bar further comprises a light absorbing layer disposed between the metal layer and the glass substrate and comprising a light absorbing material.

5. The display apparatus of claim 1, wherein the phase retardation layer retards a phase of light by λ/4, where λ is a wavelength.

6. The display apparatus of claim 1, wherein the extending direction of the linear bar is determined based on the preset polarizing direction so that the linear pattern layer transmits the light in the preset polarizing direction.

7. The display apparatus of claim 1, wherein the light emitting layer generates red, green and blue colors of light by sub-pixels.

8. A self-luminous display panel comprising:
a glass substrate;
a first electrode layer;
a second electrode layer disposed between the first electrode layer and the glass substrate;
a light emitting layer disposed between the first electrode layer and the second electrode layer, the light emitting layer being configured to generate a plurality of colors of light based on holes and electrons transported by voltage applied to the first electrode layer and the second electrode layer, and configured to emit the light to the glass substrate;
a linear pattern layer formed on a surface of the glass substrate and comprising linear bars extending in one direction to transmit the light in a preset polarizing direction; and
a phase retardation layer disposed between the second electrode layer and the linear pattern layer, and configured to emit entering light by retarding a phase of the light.

9. The display panel of claim 8, wherein the linear bar comprises a metal layer to reflect light in a polarized direction such that the linear pattern layer does not transmit the light to inside the display panel.

10. The display panel of claim 9, wherein the linear bar further comprises an insulating layer formed on a portion of the metal layer and facing toward the phase retardation layer.

11. The display panel of claim 9, wherein the linear bar further comprises a light absorbing layer disposed between the metal layer and the glass substrate and comprising a light absorbing material.

12. The display panel of claim 8, wherein the phase retardation layer retards a phase of light by λ/4, where λ is a wavelength.

13. The display panel of claim 8, wherein the extending direction of the linear pattern layer is determined based on the preset polarizing direction so that the linear pattern layer transmits the light in the preset polarizing direction.

14. The display panel of claim 8, wherein the light emitting layer generates red, green and blue colors of light by sub-pixels.

15. A self-luminous display panel comprising:
a glass substrate;
a first electrode layer;
a second electrode layer disposed between the first electrode layer and the glass substrate;
a linear pattern layer formed on a surface of the glass substrate and comprising linear bars extending in one direction to transmit light in a preset polarizing direction; and
a phase retardation layer disposed between the second electrode layer and the linear pattern layer, and configured to emit entering light by retarding a phase of the light, wherein the phase retarded light entering the self-luminous display panel, is then reflected by the first and second electrodes back towards the linear pattern layer through the phase retardation layer and is reflected back towards the phase retardation layer, whereby the entering light does not exit to the outside.
